(19) United States
(12) Patent Application Publication
(10) Pub. No.: US 2022/0252677 A1
(43) Pub. Date: Aug. 11, 2022

(54) BATTERY MANAGEMENT SYSTEM

(71) Applicant: EV Power WA Pty Ltd, Burnside (AU)

(72) Inventor: Rodney Colin Lawton Dilkes, Burnside (AU)

(21) Appl. No.: 17/669,277

(22) Filed: Feb. 10, 2022

(30) Foreign Application Priority Data
Feb. 11, 2021 (AU) 2021900330

(51) Int. Cl. G01R 31/396; G01R 31/364; G01R 31/3842; G01R 31/36

(52) U.S. Cl. CPC G01R 31/396; G01R 31/3646; G01R 31/3842; G01R 31/364

(57) ABSTRACT

A method of managing a battery using a battery management system is disclosed. The battery comprises at least a first individual cell and/or at least a first cell group, and the battery management system comprises a master battery control unit and at least one cell module connected in series by at least one signal conducting means in a single path signal loop. The method involves passing an alternating current flow control signal from the master battery control unit, along the signal conducting means and through the at least one cell module, back to the master battery control unit. The method also involves detecting a change of state in a cell connected to the at least one cell module such that passing the alternating current flow control signal through the at least one cell module is interrupted in one direction and/or the other in response to a change of state of a cell connected to the at least one cell module, and responding to the interruption in the alternating current flow control signal in the first and/or second direction by preventing charging and/or discharging of all of said at least a first individual cell and/or at least a first cell group by the master battery control unit. A corresponding battery management system is also disclosed.

### TECHNICAL FIELD

The present invention relates to battery management systems and in particular to maintaining a plurality of cells within their defined safe working voltage limits by limiting charge and discharge of the battery.

### BACKGROUND

Battery control systems using a daisy chain control signal loop are known, such as the Plug-in Hybrid Electric Vehicle (PHEV) battery management system disclosed in U.S. Pat. No. 9,184,605 which uses CAN bus signals around the daisy chain signal loop. The CAN bus arrangement is used to transmit large volumes of data, but typically CAN bus wiring uses a twisted pair of wires and cannot use a single wire connecting the elements in the daisy chain.

International patent application publication number WO2018/068523 discloses a device to be charged and a charging method. The respective control circuits of the interfaces in the monitoring system can be connected in series to the central control unit via a single wire control link to which each interface is connected via two terminals in a daisy chain fashion. The single wire control link carries control pulses in the form of successive pulse trains issued by the central control unit. The pulses are used to send requests from the central control unit to the individual interfaces and to return data from the individual interfaces to the central control unit.

Similarly, U.S. Pat. No. 5,910,723 discloses a battery management system using signalling pulses around a single wire loop between cell module and the control unit.

International patent application publication number WO98/32181 also uses a single wire communications link between the cell modules. Each cell module generates an alternating signal with frequency depending on the cell voltage, with each cell module also shifting the level of any received signals from previous modules in the daisy chain.

Each of the above arrangements requires a microprocessor in each cell module as well as in the central control unit, adding complexity and cost.

Australian patent number 2008241371 from the Applicant discloses a battery management system in which a master module controls the charging and discharging of a plurality of cells by detecting a change in the conduction of a control signal around a single wire loop through cell modules. The cell modules change the conduction of the control signal through the respective module in dependence on a change in state of the respective cell of the battery to ensure that charging and discharging is prevented when any of the cells of the battery fall outside a safe working range. While this arrangement is simpler, lower cost and more robust than the more complex arrangements, it can only indicate whether there is a fault with the arrangement, including any of the cells, but not what that fault may be. All charging and discharging is then halted for safety as the arrangement cannot differentiate between a cell being too high to charge or too low to discharge.

### SUMMARY OF INVENTION

A first aspect of the invention provides a battery management system for a battery comprising at least one cell, the battery management system comprising a master battery control unit that facilitates charging and discharging of the battery, at least one cell module and a signal conducting means; the or each cell module being individually connectable to at least one cell; the master battery control unit and the or each cell module, in use, being connected in series with each other using the signal conducting means to thereby conduct a signal from the master battery control unit through the at least one cell module and back to the master battery control unit; wherein the master battery control unit includes an alternating current control signal generator for alternately generating a first signal portion corresponding to a first current through the signal conducting means in a first direction and a second signal portion corresponding to a second current in an opposite second direction through the signal conducting means, a first signal detection circuit for detecting the first current in the first direction, and a second signal detection circuit for detecting the second current in the second direction; the or each cell module includes at least one cell state detecting means for detecting existence of a first state of a cell during use and detecting existence of a second state of the cell during use, a first signal circuit and a second signal circuit in parallel with the first signal circuit, the first and second signal circuits in series with the signal conducting means; the or each cell module configured to cause a change of the first current through the first signal circuit in response to detection of the first cell state during use, and to cause a change of the second current through the second signal circuit in response to detection of the second cell state during use; and the master battery control unit operable to detect the change of the first and/or second current, and in response to control the charging or discharging of the battery.

The cell module or at least one of the cell modules may be connectable to one cell. Additionally or alternatively, cell module or at least one of the cell modules may be connectable to multiple cells.

Alternatively, the at least one cell may comprise at least a first individual cell and/or at least a first cell group, the at least one cell module may be a respective individual cell module for a respective individual cell and/or a respective cell group module for a respective cell group, each respective individual cell module and/or each respective cell group module including at least one cell state detecting means for detecting the state of the or each cell connected thereto.

The at least one cell state detecting means may include a cell first state detecting circuit and a cell second state detecting circuit; the cell first state detecting circuit detecting when a cell voltage is above a first voltage level and operable to cause the change of the first current through the first signal circuit when the cell voltage is above the first voltage level; and the cell second state detecting circuit detecting when a cell voltage is below a second voltage level and operable to cause the change of the second current through the second signal circuit when the cell voltage is below the second voltage level, the first voltage level being greater (or higher) than the second voltage level.

The first voltage level may be an upper voltage level and the second voltage level may be a lower voltage level. For example: when any cell is over-voltage, the first signal circuit may be caused to not conduct the first signal (the break in the daisy chain signal loop in the first direction indicating that the battery should not be charged further); when any cell is under-voltage, the second signal circuit may be caused to not conduct the second signal (the break in the daisy chain signal loop in the second direction indicating that the battery should not be discharged further); when all of the cells are neither under voltage nor over voltage, the first signal circuit may conduct the first signal and the second signal circuit may conduct the second signal (the daisy chain signal loop being unbroken, indicating that charging and discharging are allowed); when one cell is over-voltage and one cell is under voltage, or when there is a broken wire in the daisy chain signal loop, the first and second signals may not be conducted around the single path signal loop, indicating a fault.

Alternatively, the at least one cell state detecting means may include a cell state detecting circuit, operable to detect cell voltage and: to cause the change of the first current through the first signal circuit when the detected cell voltage is above a predetermined first voltage level; and to cause the change of the second current through the second signal circuit when the detected cell voltage is below a predetermined second voltage level, the first voltage level being greater (or higher) than the second voltage level.

The first voltage level may be an upper voltage level and the second voltage level may be a lower voltage level. For example: when the detected voltage is above a predetermined voltage level window, the cell state detecting circuit may cause the change in the conduction of one of the first or second signal circuits; when the detected voltage is below the predetermined voltage level window, the cell state detecting circuit may cause the change in the conduction of the other one of the first or second signal circuits; and when the detected voltage is within the predetermined voltage level window, the cell state detecting circuit may cause substantially no change in the conduction of either of the first or second signal circuits.

When the detected voltage in the cell state detecting circuit of a first of the individual cell modules and/or cell group modules is above the predetermined upper voltage and the detected voltage in the cell state detecting circuit of a second of the individual cell modules and/or cell group modules is below the predetermined lower voltage, the cell module may break the daisy chain signal loop against flow in both the first and second directions, indicating a fault.

A broken wire or failed connection in the daisy chain signal loop may likewise indicate a fault.

The first signal circuit may include a first switch in series with a first unidirectional flow component, the first unidirectional flow component permitting flow in the first direction and substantially preventing flow in the second direction; and wherein the second signal circuit may include a second switch in series with a second unidirectional flow component, the second unidirectional flow component permitting flow in the second direction and substantially preventing flow in the first direction.

Each switch may be selectively opened or closed in dependence on the detected state of the cell. Each unidirectional flow component may have asymmetric conductance. The unidirectional flow component may be a diode.

The first switch may be a normally open switch which is: held closed when the at least one cell state detecting means detects the voltage of a cell below a predetermined first voltage level, and opened when the at least one cell state detecting means detects the voltage of a cell above the predetermined first voltage level. And the second switch may be a normally open switch which is: held closed when the at least one cell state detecting means detects the voltage of a cell above a predetermined second voltage level which is lower than the first voltage level, and opened when the at least one cell state detecting means detects the voltage of a cell below the predetermined second voltage level.

The conduction of the first signal through the respective individual cell or cell group module may thereby be permitted when the voltage of the associated individual cell or cell group is below the predetermined first voltage level or upper voltage level. The conduction of the first signal through the respective individual cell or cell group module may thereby be prevented when the voltage of the associated individual cell or cell group is above the predetermined first voltage level or upper voltage level, i.e. when the cell is fully charged or over-charged.

The conduction of the second signal through the respective individual cell or cell group module may thereby be permitted when the voltage of the associated individual cell or cell group is above the predetermined second voltage level or lower voltage level. The conduction of the second signal through the respective individual cell or cell group module may thereby be prevented when the voltage of the associated individual cell or cell group is below the predetermined second voltage level or lower voltage level, i.e. when the cell is flat or under-charged.

When the switches are normally open, if there is a fault including one of the cells or cell groups being too low or flat to power the relay, or a break in the wire connecting the cell modules in series in the daisy chain signal loop to the battery control module, then the daisy chain signal loop may be broken in both the first and second directions, indicating an error or fault to the battery control unit and preventing any charging or discharging of the battery.

The first switch may be a relay and/or the second switch may be a relay. Alternatively, the first switch may be an opto-isolator and/or the second switch may be an opto-isolator.

The conducting means may be a single path conducting means connecting the master battery control unit and the or each cell module in series. For example, the conducting means may be a single wire or a single core wire connecting all of the modules and the control unit in series forming the daisy chain loop.

Another aspect of the present invention provides a battery management system for a battery comprising at least a first individual cell and/or at least a first cell group, the battery management system comprising a master battery control unit, at least one cell module and at least one signal conducting means; the master battery control unit comprising or being connected to a charging and discharging unit for charging and discharging the battery; the at least one cell module being a respective individual cell module and/or a respective cell group module for each of the at least a first individual cell and/or each of the at least a first cell group; in use, the or each individual cell module and/or cell group module being coupled to the respective individual cell and/or respective group of cells; the master battery control unit and the or each respective individual cell module and/or the or each respective cell group module being connected in series with each other by means of the at least one signal conducting means forming a daisy chain signal loop, thereby conducting a signal from the master battery control unit through the at least one cell module and back to the master battery control unit; wherein the master battery control unit includes an alternating current signal generator, a first signal detection circuit for detecting current flow in a first direction and a second signal detection circuit for detecting current flow in an opposite or a second direction; the alternating current signal generator alternately generating a first signal in the first direction and a second signal in the second direction, the or each respective individual cell module and/or the or each respective cell group module includes at least one cell state detecting means, a first signal circuit and a second signal circuit in parallel with the first signal circuit, the at least one cell state detecting means of the respective individual cell module and/or the respective cell group module being operable to detect a state of the cell or group of cells coupled thereto in use, such that: a detected state of a cell or group of cells being below a predetermined upper or first voltage causes conduction of the first signal to be permitted through the respective individual cell or cell group module, whereas the detected state of a cell or group of cells being above the predetermined upper or first voltage causes conduction of the first signal to be prevented through the respective individual cell or cell group module; and a detected state of a cell or group of cells being above a predetermined lower or second voltage, which is lower than the upper or first voltage, causes conduction of the second signal to be permitted through the respective individual cell or cell group module, whereas the detected state of a cell or group of cells being below the predetermined lower or second voltage causes conduction of the second signal to be prevented through the respective individual cell or cell group module; the master battery control unit being operable to set the charging and discharging unit to discharging in response to detecting a lack of conduction of the first signal and a conduction of the second signal; and/or the master battery control unit being operable to set the charging and discharging unit to charging in response to detecting conduction of the first signal and a lack of conduction of the second signal; and/or the master battery control unit being operable to prevent the charging and discharging unit from charging or discharging in response to detecting a lack of conduction of the first signal and a lack of conduction of the second signal.

The conducting means may be a single path conducting means connecting the master battery control unit and the or each respective individual cell module and/or the or each respective cell group module together in series in the daisy chain signal loop.

Another aspect of the present invention provides a method of managing a battery comprising at least a first individual cell and/or at least a first cell group, the battery management system comprising a master battery control unit and at least one cell module connected in series by at least one signal conducting means in a single path signal loop; the method including the steps of: passing an alternating current flow control signal from the master battery control unit, along the signal conducting means and through the at least one cell module, back to the master battery control unit; detecting a change of state in a cell connected to the at least one cell module such that passing the alternating current flow control signal through the at least one cell module is interrupted in one direction and/or the other in response to a change of state of a cell connected to the at least one cell module; responding to the interruption in the alternating current flow control signal in the first and/or second direction by preventing charging and/or discharging of all of said at least a first individual cell and/or at least a first cell group by the master battery control unit.

Another aspect of the present invention provides a method of managing a battery comprising at least a first individual cell and/or at least a first cell group, the battery management system comprising a master battery control unit and a respective cell module for each cell or group of cells, the master battery control unit and the at least one cell module being of the connected in series by at least one signal conducting means in a daisy chain signal loop; the method including the steps of: attempting to pass an alternating current flow control signal from the master battery control unit, along the signal conducting means and through the at least one cell module, back to the master battery control unit, a first control signal being in a first direction and a second control signal being in an opposite, second direction around the daisy chain signal loop; the or each cell module detecting a state of a respective cell or group of cells; if the detected state of a cell or group of cells is below a predetermined upper or first voltage then causing conduction of the first signal to be permitted through the respective individual cell or cell group module in the first direction, or if the detected state of a cell or group of cells is above the predetermined upper or first voltage, then causing conduction of the first signal to be prevented through the respective individual cell or cell group module; if the detected state of a cell or group of cells is above a predetermined lower or second voltage, which is lower than the upper or first voltage, then causing conduction of the second signal to be permitted through the respective individual cell or cell group module in the second direction, or if the detected state of a cell or group of cells is below the predetermined lower voltage causes conduction of the second signal to be prevented through the respective individual cell or cell group module; sensing conduction of the first control signal and the second control signal around the daisy chain loop using the master battery control unit: setting the charging and discharging unit to discharging if a lack of conduction of the first signal is detected and a conduction of the second signal is detected; and/or setting the charging and discharging unit to charging if conduction of the first signal is detected and a lack of conduction of the second signal is detected; and/or flagging and/or indicating a fault and preventing the charging and discharging unit from charging or discharging if a lack of conduction of the first signal and a lack of conduction of the second signal are both detected.

### BRIEF DESCRIPTION OF DRAWINGS

In the drawings:

FIG. 1 is a schematic diagram of a battery management system according to an embodiment of the present invention.

FIG. 2 is a schematic diagram of the battery management system of FIG. 1 including a group of cells.

FIG. 3 is a schematic diagram of a cell and cell module of FIG. 1.

FIG. 4 is a schematic diagram of an alternative master battery control unit of an embodiment of the present invention.

FIG. 5 is a schematic diagram of a further alternative master battery control unit of an embodiment of the present invention.

FIG. 6 is a flow diagram of the operation of a cell module of an embodiment of the present invention.

FIG. 7 is a flow diagram of the operation of a master battery control unit of an embodiment of the present invention.

### DESCRIPTION OF PREFERRED EMBODIMENT

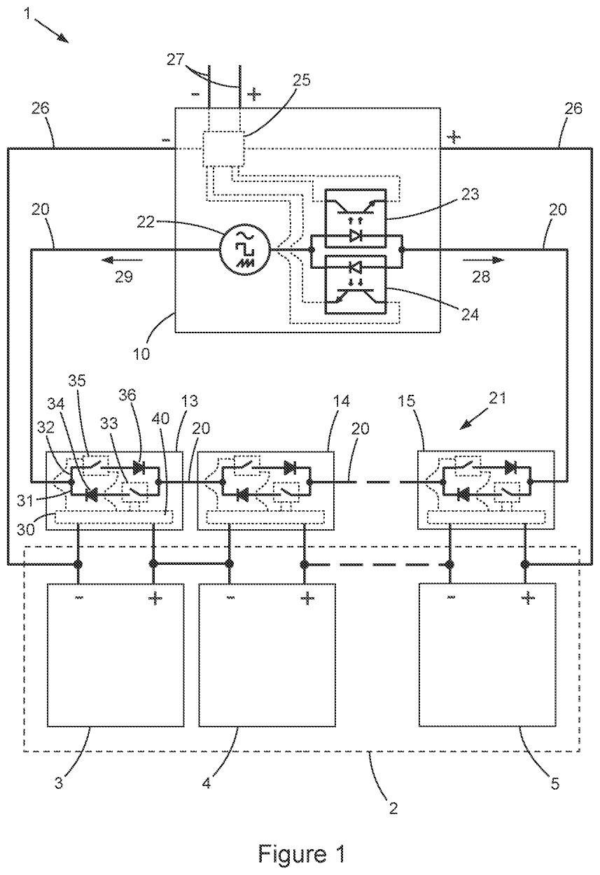

Referring initially to FIG. 1 there is shown a battery management system 1 which helps ensure the safe operation and maintenance of a battery 2. The battery 2 can have any number of electrochemical storage cells, such as lithium-ion cells and in the example shown, has a first cell 3, a second cell 4 and an n^{th} cell 5, as denoted by the dashed portions of the signal conducting means 20 and the battery connections 26. A respective cell module 13, 14, 15 is connected to each individual cell 3, 4, 5 to monitor the state of the cell. Signal conducting means 20 such as single core wire connect the cell modules 13, 14, 15 and the master battery control unit 10 in series. The arrangement of components in series in a single wire signal loop is typically known as a “daisy chain” signal loop 21.

The master battery control unit 10 houses an alternating current control signal generator 22 which generates an alternating voltage to attempt to generate a first current flow in a first direction 28, then a second current flow in a second direction 29, the signal current flowing in alternating directions as long as the daisy chain signal loop 21 is conductive. The waveform of a first signal portion alternating with a second signal portion can be sinusoidal, square, saw or any other alternating waveform. The alternating current signal generator could even generate a voltage in the first direction, then go to zero for a period before generating a voltage in the opposite second direction, i.e. the signal does not need to be a completely continuous waveform, but must alternate in polarity.

The first signal detection circuit 23 in the master battery control unit 10 detects the first current flow in the first direction 28 and is connected to the controller and charging and discharging unit 25. Similarly, the second signal detection circuit 24 in the master battery control unit 10 detects the second current flow in the second direction 29 and is connected to the controller and charging and discharging unit 25.

Each cell module 13, 14, 15 is powered by the associated cell 3, 4, 5 and includes a cell state detecting means 30, a first signal circuit 31 and a second signal circuit 32. The second signal circuit 32 is in parallel with the first signal circuit 31. The first signal circuit 31 includes a first switch 33 in series with a diode or any equivalent first unidirectional flow component 34 to permit current flow in the first direction only. Similarly, the second signal circuit 32 includes a second switch 35 in series with a diode or any equivalent second unidirectional flow component 36 to permit current flow in the second direction only. The first and second switches 33, 35 are preferably normally open switches so in the event of a failure, they are open, breaking the daisy chain signal loop 21.

The cell state detecting means 30, which includes at least one electronic cell monitoring module circuit or cell state detecting circuit 40, monitors whether the cell is under-voltage or over-voltage. If the cell is not over-voltage, then the first switch 33 is held in the closed position. Conversely, if the cell state detecting circuit 40 detects that the cell is over-voltage, the first switch 33 is caused to open. Similarly, if the cell is not under-voltage, then the second switch 35 is held in the closed position, but if the cell state detecting circuit 40 detects that the cell is under-voltage, the second switch 35 is caused to open.

Therefore, when the cell 3 is within its predetermined voltage range or operating window, both switches are held closed and the cell module 13 is able to conduct the first and second currents of the first and second signal portions, i.e. current can flow through the cell module 13 in the first and second directions 28, 29. When the cell 3 is over-voltage, first signal circuit 31 of the cell module 13 is open circuit so cannot conduct the first signal portion. When the cell 3 is under-voltage, second signal circuit 32 of the cell module 13 is open circuit so cannot conduct the second signal portion.

Therefore, when any cell is over-voltage, flow of the first current (of the first signal portion) around the daisy chain signal loop is prevented. The first signal detection circuit 23 in the master battery control unit 10 detects the lack of the first current flow in the first direction 28 and thereby signals to the controller that the battery should be discharged. When any cell is under-voltage, flow of the second current (of the second signal portion) around the daisy chain signal loop is prevented. The second signal detection circuit 24 in the master battery control unit 10 detects the lack of the second current flow in the second direction 29 and thereby signals to the controller that the battery should be discharged. The controller and charging and discharging unit 25 is connected to the battery connections 26 and to external power connections 27.

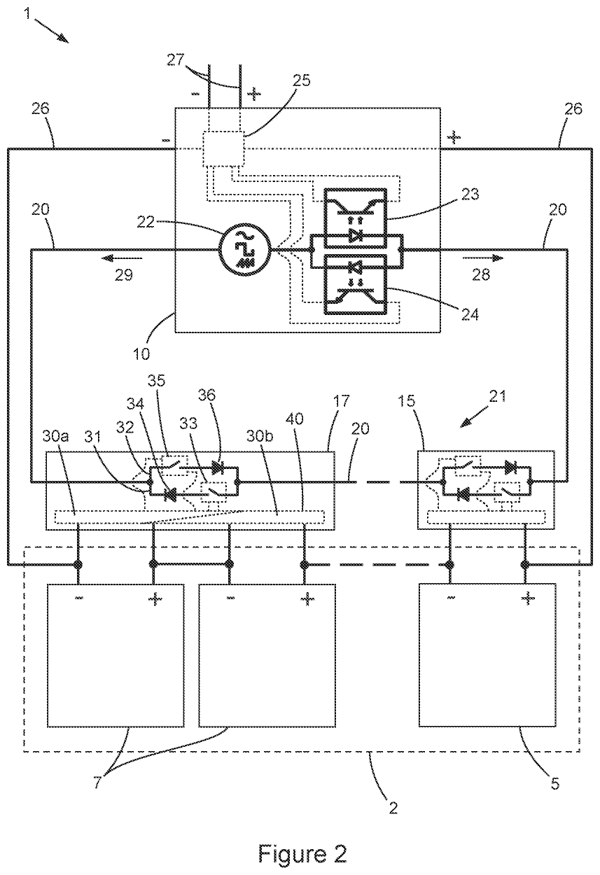

In FIG. 2, the cell module 17 is connected to multiple cells of the battery 2, i.e. a cell module can optionally monitor more than one individual cell. The first cell group module 17 monitors a first cell group 7 and the cell state detecting circuit 40 includes a first cell state detecting means 30a for detecting the state of a first one of the cells in the cell group 7 and a second cell state detecting means 30b for detecting the state of a second one of the cells in the cell group 7. The cell state detecting circuit 40 operates the first and second switches 33, 35 in the parallel first and second signal circuits 31, 32. Only the one set of the first and second signal circuits is required for the cell group module 17 to enable the module to indicate the state of the connected cells.

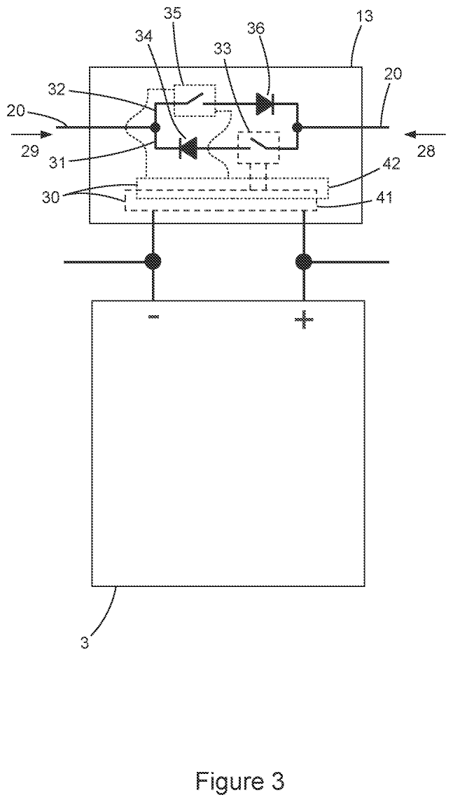

In FIG. 3, the cell module 13 for the cell 3 has an alternative arrangement of cell state detecting means 30 including individual cell first and second state detecting circuits. A cell first state detecting circuit 41 detects over-voltage of the cell 3, so holds the switch 33 of the first signal circuit 31 closed while the cell is not over-voltage, but opens the switch 33 when the cell 3 is over-voltage. A cell second state detecting circuit 42 detects under-voltage of the cell 3, so holds the switch 35 of the second signal circuit 32 closed while the cell is not under-voltage, but opens the switch 35 when the cell 3 is under-voltage.

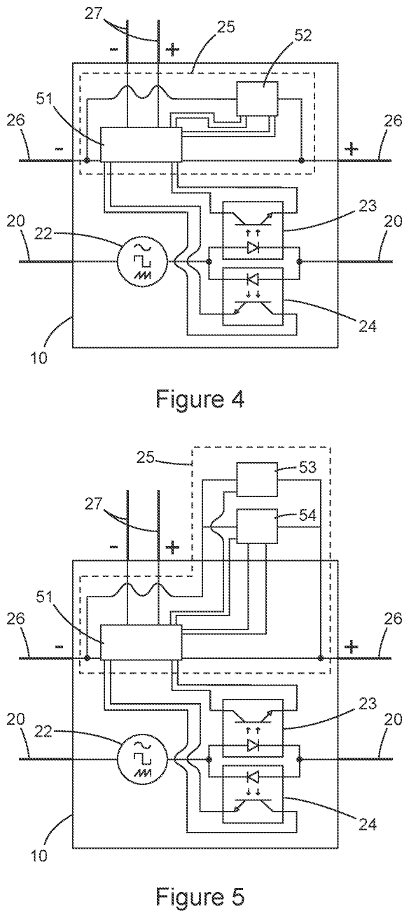

In the master battery control unit 10 in FIG. 4, the controller and charging and discharging unit 25 is shown in more detail. It includes a controller 51 which is connected to the first and second signal detection circuits 23, 24 and controls the charging and discharging unit 52 which is connected to the battery connections 26. The controller 51 also controls the external power connections 27. Preferably the controller 51 is powered by the battery.

In FIG. 5, the charging and discharging units are external to the master battery control unit 10. For example, the discharge unit 53 can be a load which is selectively communicated with the battery connections 26, the selective communication being controlled by the controller 51. The charging unit 54 can be a charger which selectively charges the battery.

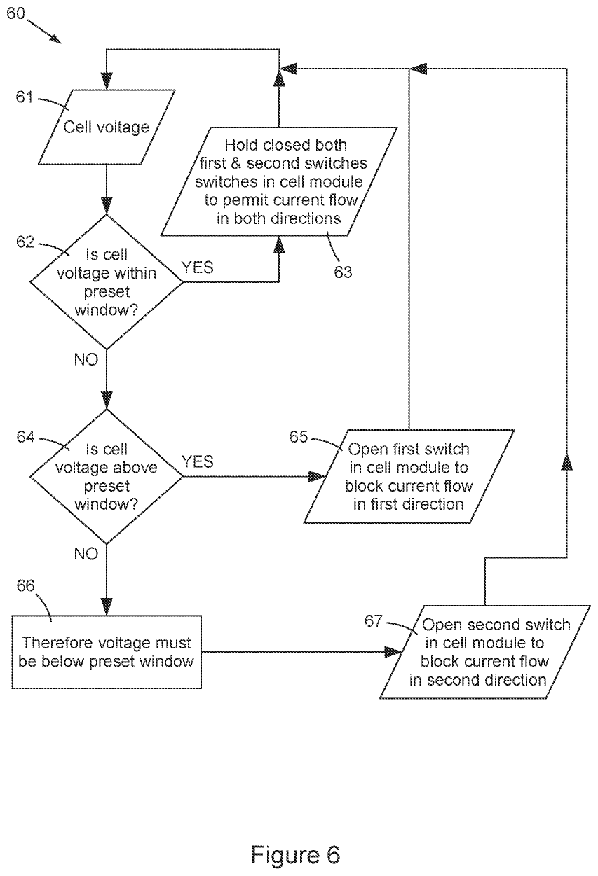

The flow diagram 60 in FIG. 6 shows an example of the operation of one of the cell modules. In the cell voltage input step 61, the voltage of the cell is input to the cell state detecting means. A voltage window evaluation 62 is made to determine whether the cell voltage is with a preset or predetermined window. If the cell voltage is within the predetermined window, the close switches output 63 is made to indicate the cell is within the desired voltage range or voltage window.

When the voltage window evaluation 62 is made, if the cell voltage is not within the preset window, then an over-voltage evaluation 64 is made to determine whether the cell is over-voltage. If the cell voltage is above the preset window, i.e. the cell is over-voltage and needs discharging, then the open first switch in cell module action 65 is taken which will prevent current flow through the first signal circuit of the cell module.

However, if the cell voltage is not above the preset window, then the cell module logically determines 66 that it must be below the preset window, i.e. under-voltage and need charging, so proceeds to the open the second switch action 67 which will prevent current flow through the second signal circuit of the cell module.

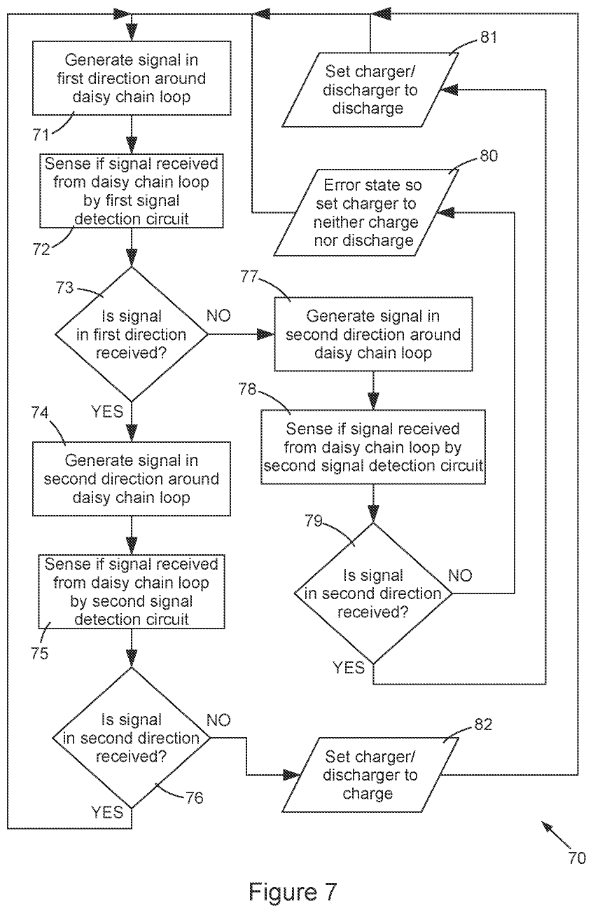

The flow diagram 70 in FIG. 7 shows the operation of the master battery control unit. The first step is to generate a signal in the first direction 71 and then to sense whether the first current is detected by the first signal detection circuit 72. If the signal in the first direction is received 73, then generate a signal in the second direction 74 and then sense whether the second current is detected by the second signal detection circuit 75. If the second signal is received 76, then all the cells of the battery are within the desired window or voltage range, so no action is taken and the operation returns to generate a signal in the first direction 71.

If however the signal in the first direction is not received 73, then the master battery control unit generates a signal in the second direction 77 and then senses whether the second signal is received by the second signal detection circuit 78. If the second signal is not received 79, then that means both the first and second signals have not been received, i.e. the daisy chain signal loop is broken in both directions. This indicates an error state so the controller sets the charging discharging unit to neither charge nor discharge 80. The error state can be from one cell being over-voltage and one cell being under-voltage, which indicates a problem with the battery which needs intervention, or the error state can be from a broken wire for example, which again requires intervention to correct.

If the signal in the first direction is not received 73 (i.e. at least one cell is over-voltage) but the signal in the second direction is received 79, that indicates that although at least one cell is over-voltage, it is safe to discharge, so the charging and discharging unit is set to discharge 81 the battery.

Conversely, if the signal in the first direction is received 73 (i.e. no cells are over voltage so safe to charge) but the signal in the second direction is not received 76, that indicates that at least one cell is under-voltage, so the charging and discharging unit is set to charge 82 the battery.

It should be noted that the battery management system may be manufactured and shipped without any batteries. The cell modules can be fitted to the cell of a battery during installation. Similarly, the cell modules and conducting means may not all be assembled to the master battery control unit when the battery management system is shipped, the connections being made during installation.

In the claims which follow and in the preceding description, except where the context requires otherwise due to express language or necessary implication, the word “comprise” or variations such as “comprises” or “comprising” is used in an inclusive sense, i.e. to specify the presence of the stated features but not to preclude the presence or addition of further features in various embodiments.

It is to be understood that, if any prior art publication is referred to herein, such reference does not constitute an admission that the publication forms a part of the common general knowledge in the art, in Australia or any other country.

The above description of the example Figures describes possible embodiments of the present invention but should not be seen as limiting the following claims as modifications within the scope of the claims that may be apparent to one skilled in the art are considered to be within the scope of the invention.

1. A battery management system for a battery comprising at least one cell, the battery management system comprising a master battery control unit that facilitates charging and discharging of the battery, at least one cell module and a signal conducting means;
the or each cell module being individually connectable to at least one cell;
the master battery control unit and the or each cell module, in use, being connected in series with each other using the signal conducting means to thereby conduct a signal from the master battery control unit through the at least one cell module and back to the master battery control unit;
wherein the master battery control unit includes an alternating current control signal generator for alternately generating a first signal portion corresponding to a first current through the signal conducting means in a first direction, and a second signal portion corresponding to a second current in an opposite second direction through the signal conducting means, a first signal detection circuit for detecting the first current in the first direction, and a second signal detection circuit for detecting the second current in the second direction;
the or each cell module including at least one cell state detecting means for detecting existence of a first state of a cell during use and detecting existence of a second state of the cell during use, a first signal circuit, and a second signal circuit in parallel with the first signal circuit, the first and second signal circuits in series with the signal conducting means;
the or each cell module configured to cause a change of the first current through the first signal circuit in response to detection of the first cell state during use, and to cause a change of the second current through the second signal circuit in response to detection of the second cell state during use; and
the master battery control unit operable to detect the change of the first and/or second current, and in response to control the charging or discharging of the battery.

2. A battery management system as claimed in claim 1, wherein the cell module or at least one of the cell modules is connectable to one cell.

3. A battery management system as claimed in claim 1, wherein the cell module or at least one of the cell modules is connectable to multiple cells.

4. A battery management system as claimed in claim 1, wherein the at least one cell comprises at least a first individual cell and/or at least a first cell group,
the at least one cell module being a respective individual cell module for a respective individual cell and/or being a respective cell group module for a respective cell group,
each respective individual cell module and/or each respective cell group module including at least one cell state detecting means for detecting the state of the or each cell connected thereto.

5. A battery management system as claimed in claim 1, wherein the at least one cell state detecting means includes a cell first state detecting circuit and a cell second state detecting circuit,
the cell first state detecting circuit detecting when a cell voltage is above a first voltage level and operable to cause the change of the first current through the first signal circuit when the cell voltage is above the first voltage level; and
the cell second state detecting circuit detecting when a cell voltage is below a second voltage level and operable to cause the change of the second current through the second signal circuit when the cell voltage is below the second voltage level;
the first voltage level being greater than the second voltage level.

6. A battery management system as claimed in claim 1, wherein the at least one cell state detecting means includes a cell state detecting circuit, operable to detect cell voltage and:
to cause the change of the first current through the first signal circuit when the detected cell voltage is above a predetermined first voltage level;
to cause the change of the second current through the second signal circuit when the detected cell voltage is below a predetermined second voltage level;
the first voltage level being greater than the second voltage level.

7. A battery management system as claimed in claim 1, wherein the first signal circuit includes a first switch in series with a first unidirectional flow component,
the first unidirectional flow component permitting flow in the first direction and substantially preventing flow in the second direction; and
wherein the second signal circuit includes a second switch in series with a second unidirectional flow component,
the second unidirectional flow component permitting flow in the second direction and substantially preventing flow in the first direction.

8. A battery management system as claimed in claim 7:
wherein the first switch is a normally open switch which is:
held closed when the at least one cell state detecting means detects a cell voltage below a predetermined first voltage level, and
opened when the at least one cell state detecting means detects a cell voltage above the predetermined first voltage level; and
wherein the second switch is a normally open switch which is:
held closed when the at least one cell state detecting means detects a cell voltage above a predetermined second voltage level which is lower than the first voltage level, and
opened when the at least one cell state detecting means detects a cell voltage below the predetermined second voltage level.

9. A battery management system as claimed in claim 7, wherein the first switch is a relay and/or the second switch is a relay.

10. A battery management system as claimed in claim 7, wherein the first switch is an opto-isolator and/or the second switch is an opto-isolator.

11. A battery management system as claimed in claim 1 wherein the conducting means is a single path conducting means connecting the master battery control unit and the or each cell module in series.

12. A battery management system for a battery comprising at least a first individual cell and/or at least a first cell group, the battery management system comprising a master battery control unit, at least one cell module and at least one signal conducting means;
the master battery control unit comprising or being connected to a charging and discharging unit for charging and discharging the battery;
the at least one cell module being a respective individual cell module and/or a respective cell group module for each of the at least a first individual cell and/or each of the at least a first cell group;
in use, the or each individual cell module and/or cell group module being coupled to the respective individual cell and/or respective group of cells;
the master battery control unit and the or each respective individual cell module and/or the or each respective cell group module being connected in series with each other by means of the at least one signal conducting means forming a daisy chain signal loop, thereby conducting a signal from the master battery control unit through the at least one cell module and back to the master battery control unit,
wherein the master battery control unit includes an alternating current signal generator, a first signal detection circuit for detecting current flow in a first direction and a second signal detection circuit for detecting current flow in an opposite or a second direction; the alternating current signal generator alternately generating a first signal in the first direction and a second signal in the second direction,
the or each respective individual cell module and/or the or each respective cell group module includes at least one cell state detecting means, a first signal circuit and a second signal circuit in parallel with the first signal circuit,
the at least one cell state detecting means of the respective individual cell module and/or the respective cell group module being operable to detect a state of the cell or group of cells coupled thereto in use, such that:
a detected state of a cell or group of cells being below a predetermined upper or first voltage causes conduction of the first signal to be permitted through the respective individual cell or cell group module, whereas the detected state of a cell or group of cells being above the predetermined upper or first voltage causes conduction of the first signal to be prevented through the respective individual cell or cell group module,
a detected state of a cell or group of cells being above a predetermined lower or second voltage, which is lower than the upper or first voltage, causes conduction of the second signal to be permitted through the respective individual cell or cell group module, whereas the detected state of a cell or group of cells being below the predetermined lower or second voltage causes conduction of the second signal to be prevented through the respective individual cell or cell group module,
the master battery control unit being operable to set the charging and discharging unit to discharging in response to detecting a lack of conduction of the first signal and a conduction of the second signal; and/or
the master battery control unit being operable to set the charging and discharging unit to charging in response to detecting conduction of the first signal and a lack of conduction of the second signal; and/or
the master battery control unit being operable to prevent the charging and discharging unit from charging or discharging in response to a detected a lack of conduction of the first signal and a lack of conduction of the second signal.

13. A method of managing a battery comprising at least a first individual cell and/or at least a first cell group using a battery management system, the battery management system comprising a master battery control unit and at least one cell module connected in series by at least one signal conducting means in a single path signal loop; the method including the steps of:
passing an alternating current flow control signal from the master battery control unit, along the signal conducting means and through the at least one cell module, back to the master battery control unit;
detecting a change of state in a cell connected to the at least one cell module such that passing the alternating current flow control signal through the at least one cell module is interrupted in one direction and/or the other in response to a change of state of a cell connected to the at least one cell module;
responding to the interruption in the alternating current flow control signal in the first and/or second direction by preventing charging and/or discharging of all of said at least a first individual cell and/or at least a first cell group by the master battery control unit.

14. A method of managing a battery comprising at least a first individual cell and/or at least a first cell group using a battery management system, the battery management system comprising a master battery control unit and a respective cell module for each cell or group of cells, the master battery control unit and the at least one cell module being of the connected in series by at least one signal conducting means in a daisy chain signal loop; the method including the steps of:
attempting to pass an alternating current flow control signal from the master battery control unit, along the signal conducting means and through the at least one cell module, back to the master battery control unit, a first signal portion of the alternating current flow control signal corresponding to a first current in a first direction and a second signal portion corresponding to a second current in an opposite second direction around the daisy chain signal loop;
the or each cell module detecting a state of a respective cell or group of cells;
if the detected state of a cell or group of cells is below a predetermined first voltage then causing conduction of the first signal portion to be permitted through the respective individual cell or cell group module in the first direction, or
if the detected state of a cell or group of cells is above the predetermined first voltage, then causing conduction of the first signal portion to be prevented through the respective individual cell or cell group module;
if the detected state of a cell or group of cells is above a predetermined second voltage, which is lower than the first voltage, then causing conduction of the second signal portion to be permitted through the respective individual cell or cell group module in the second direction, or
if the detected state of a cell or group of cells is below the predetermined second voltage causes conduction of the second signal portion to be prevented through the respective individual cell or cell group module,
sensing conduction of the first signal portion and the second signal portion around the daisy chain loop using the master battery control unit:
setting the charging and discharging unit to discharging if a lack of conduction of the first signal portion is detected and a conduction of the second signal portion is detected; and/or
setting the charging and discharging unit to charging if conduction of the first signal portion is detected and a lack of conduction of the second signal portion is detected; and/or
flagging and/or indicating a fault and preventing the charging and discharging unit from charging or discharging if a lack of conduction of the first signal portion and a lack of conduction of the second signal portion are both detected.
